(19) United States
(12) Patent Application Publication
(10) Pub. No.: US 2026/0142119 A1
(43) Pub. Date: May 21, 2026

(54) GRID BOX FOR ELECTRON MICROSCOPE SAMPLE CARRIERS

(71) Applicant: FEI Company, Hillsboro, OR (US)

(72) Inventors: Maarten Kuijper, Helmond (NL); Swen Hellenbrand, Veldhoven (NL); Pascal Ronal Treur, Tilburg (CZ); John Marks Mitchels, Klobouky u Brna (CZ); Michal Valík, Neslovice, Jihomoravský kraj (CZ); Václav Batelka, Tišnov, Jihomoravský kraj (CZ); Veronika Vrbovská, Brno (CZ)

(21) Appl. No.: 19/390,822

(22) Filed: Nov. 17, 2025

Related U.S. Application Data
(60) Provisional application No. 63/721,416, filed on Nov. 15, 2024.

(51) Int. Cl. H01J 37/20

(52) U.S. Cl. CPC H01J 37/20; H01J 2237/2001; H01J 2237/2002

(57) ABSTRACT

A first grid box assembly for holding a plurality of sample-bearing grids for use in cryo-electron microscopy comprises: a grid box comprising a plurality of compartments, each compartment adapted to hold a respective sample-bearing grid on a sample carrier; and a sample grid stabilization apparatus comprising a plurality of spring arms, wherein each spring arm provides a spring force to a respective sample carrier that secures the position of the sample carrier within its respective compartment. A second grid box assembly for holding a plurality of sample-bearing grids for cryo-electron microscopy comprises: a grid box comprising a plurality of compartments, each compartment adapted to hold a respective sample-bearing grid on a sample carrier; and a lid adapted to cover a top surface of the grid box, wherein a bottom surface of the grid box comprises a plurality of gas dispersion pockets the extend to the perimeter of the grid box.

### CROSS-REFERENCE TO RELATED APPLICATION

This application claims, under 35 U.S. C § 119(e)(1), the right of priority to and the benefit of the filing date of co-pending U.S. Provisional Application 63/721,416, titled “Gridbox for Electron Microscope Sample Carriers”, which was filed on Nov. 15, 2024, the disclosure of which is hereby incorporated herein by reference in its entirety.

### TECHNICAL FIELD

The present application relates to sample preparation and storage of samples for electron microscopic analyses. More particularly, the present application relates to the structures and components of grid boxes that are used for storing, organizing and handling delicate sample carrier devices that bear samples that are to be or that have been studied by electron microscopy and, especially, by cryogenic electron microscopy.

### INCORPORATION BY REFERENCE

All patents, patent application publications and other published articles mentioned herein are hereby incorporated by reference herein in their entirety as if set forth fully herein.

### BACKGROUND

Cryogenic electron microscopy (cryo-EM) has revolutionized the field of structural biology by providing means for studying delicate structures of proteins, ribosomes, viruses, various other biomolecules and whole cells in their native state and without damaging molecular and biological structures. This technique allows scientists to visualize the intricate details of such molecules and cells, which is essential for understanding their functioning, especially with regard to drug design. Cryo-EM involves freezing biological samples to cryogenic temperatures, typically using liquid ethane or a mixture of liquid ethane and propane. This rapid freezing process preserves the native structure of the sample by embedding it in vitreous ice, a glass-like form of water that prevents the formation of ice crystals which can damage the sample. The frozen samples are then analyzed using specially-designed electron microscopes. For example, specially-designed transmission electron microscopes (cryo-TEMs) are useful for such studies. Such cryo-TEM microscopes use an electron beam to pass through the sample, creating images that can be used to reconstruct high-resolution three-dimensional models of the sample.

Sample-bearing electron microscopy carriers are crucial components that are used to support the ultrathin specimens that are imaged or analyzed by electron microscopes. The carrier may be a single-component structure on which the sample is attached directly on a feature of the carrier (e.g., see FIG. 5). Alternatively, a primary sample carrier may hold a secondary grid structure grid structure (e.g., see FIG. 4). Such secondary grid structures (so-called grids), may be used to support samples for electron microscopic studies under a variety of experimental conditions, including room-temperature conditions as well as cryogenic conditions. The grids are typically mesh structures that are made of metals such as copper, nickel, or gold. These metals are chosen for their stability under the electron beam and their ability to conduct electricity, which helps to dissipate the charge that can build up during imaging. The grids are often circular with a diameter of about 3.05 mm so as to fit into a grid holder of a transmission electron microscope (TEM). Generally, a grid is about 25-50 micrometers in thickness and consists of a mesh with a regular pattern of square or hexagonal holes. The mesh size can vary, but common sizes include 100, 200, 300, or 400 mesh, where the number indicates the number of holes per inch. The mesh provides a support structure for the sample while allowing the electron beam to pass through the holes. A thin support film is often applied to the grid to hold the specimen. The support film is typically less than 10 nm thick to minimize interference with the electron beam and to reduce background noise in the images. The support film can be continuous or holey.

Holey films are particularly useful for cryo-EM, where the sample is embedded in vitreous ice. For such studies, the grid may be plunge-frozen in liquid ethane to preserve the native structure of the sample in vitreous ice.

An electron microscope grid box is designed to store and protect the delicate carriers that are used in electron microscopy. As used herein, the term “grid box” refers to devices that store and protect sample carriers that comprise mesh-like grid structures on which samples are disposed as well as to devices that store and protect sample carriers on which samples are disposed but that do not comprise grid structures. In general, an electron microscope grid box includes one or more slots or compartments that are individual sections within the grid box where each sample carrier can be securely placed. The slots are often numbered or labeled to facilitate easy identification and organization of the sample carriers. Typically, a grid box has a lid or cover that can be securely closed to protect the grids. Many available grid boxes come with a built-in labeling system, such as numbered slots or spaces in order to keep track of the various samples.

With particular reference to cryo-TEM studies, grid boxes may be used to organize and store multiple TEM sample carriers before and after a flash-freezing process. Generally, each sample is initially prepared and loaded onto a sample carrier at room temperature. The sample carrier with sample is then flash-frozen in a cryogenic liquid such as liquid ethane. Alternatively, samples may be flash-frozen first and then placed onto the sample carrier. Once the sample carrier with frozen sample is created, it is quickly transferred, using cryo-tweezers, to a grid box slot in a grid box that is maintained at cryogenic temperature. During this process, each sample carrier must be securely positioned within the grid box to avoid movement or damage during storage and transport. Grid boxes with their respective samples are stored in liquid nitrogen until they are ready for analysis. At that time, each sample carrier having samples to be analyzed is carefully transferred from the grid box to a cryo-EM grid holder.

With the increasing use of cryo-EM in biological research and clinical studies, and the consequent increase in the number of samples to be studied, there is a need to improve the efficiency of the cryogenic sample carrier loading, sample carrier storage and sample carrier unloading processes and to devise additional means for protecting delicate sample-bearing grids from damage during handling. This disclosure addresses such needs.

### SUMMARY

New unified grid boxes with removable lids are described. The new grid boxes can store multiple cryogenic electron microscopy (cryo-EM) sample carriers and can be used to store the samples under liquid nitrogen conditions and/or transport the samples between cryo-EM workflow stations. The new designs provide several distinct performance improvements over the previous grid box designs and provide several new functions.

According to a first aspect of the present teachings, a grid box assembly for holding a plurality of sample-bearing sample carriers for use in electron microscopy comprises:
a grid box comprising a plurality of compartments, each compartment adapted to hold a respective sample-bearing sample carrier; and
a sample grid stabilization apparatus comprising a plurality of spring arms, wherein each spring arm provides a spring force to a respective sample carrier that secures the position of the sample carrier within its respective compartment.

In various embodiments, the grid box assembly may comprise a lid. The lid may be transparent. In various embodiments, the lid may comprise:
a cover plate;
a boss extending from a lower surface of the cover plate for fastening the lid to the grid box; and
a stem and a pair of fins extending from an upper surface of the cover plate for engagement with a tool that rotates the lid for attachment to and detachment from the grid box.

In various embodiments, the sample grid stabilization apparatus may be fabricated from polycarbonate. In various embodiments, a perimeter surface of the grid box that may be engraved with a unique identifying coding. In various embodiments, a perimeter surface of the grid box that may be engraved with a unique identifying coding.

According to a second aspect of the present teachings, a grid box assembly for holding a plurality of sample-bearing grids for use in electron microscopy comprises:
a grid box comprising a plurality of compartments, each compartment adapted to hold a respective sample-bearing sample carrier; and
a lid adapted to cover a top surface of the grid box,
wherein a bottom surface of the grid box comprises a plurality of gas dispersion pockets through which gas resulting from evaporation of liquid below the device may escape.

According to a third aspect of the present teachings, a kit for use in cryo-electron microscopy comprises:
a plurality of grid boxes, each grid box comprising a plurality of sample compartments for storing sample-bearing grids on sample carriers;
a plurality of lids, each lid adapted to engage with a top surface of any one of the grid boxes,
wherein each grid box is encoded with one of plurality of color-coding schemes and wherein at least one of the color-coding schemes comprises more than one color.

According to a fourth aspect of the present teachings, a method of preparing and storing a plurality of samples for cryo-electron microscopy analysis comprises:
loading a grid box into a sample preparation device that is maintained at cryogenic temperature, the grid box having a bottom surface that comprises a plurality of gas dispersion pockets;
embedding the samples in vitreous ice by freezing the samples in liquid coolant;
loading a plurality of sample carriers with the frozen samples into respective compartments of the grid box in the sample preparation device;
attaching a lid having a threaded boss on a bottom side of the lid to a top surface of the grid box by rotating the lid so that the threaded boss engages with a threaded hole in the grid box;
removing the grid box with the stored grid carriers from the sample preparation device; and
storing the grid box with the grid carriers in a cryogenic liquid.

According to another aspect of the present teachings, a kit for use in storage of cryo-electron microscopy samples comprises:
a plurality of grid boxes, each grid box comprising a plurality of sample compartments for storing sample-bearing sample carriers;
a plurality of lids, each lid adapted to engage with a top surface of any one of the grid boxes,
wherein each grid box is encoded with one of plurality of color-coding schemes and wherein at least one of the color-coding schemes comprises more than one color.

According to yet another aspect of the present teachings, a kit for use in storage of cryo-electron microscopy samples comprises:
a plurality of grid boxes, each grid box comprising a plurality of sample compartments for storing sample-bearing sample carriers; and
a plurality of lids, each lid adapted to engage with a top surface of any one of the grid boxes,
wherein each grid box has a bottom surface that comprises a plurality of gas dispersion pockets.

### BRIEF DESCRIPTION OF THE DRAWINGS

The above noted and various other aspects of the present invention will become apparent from the following description which is given by way of example only and with reference to the accompanying drawings, not necessarily drawn to scale, in which:

FIG. 1A is a top view depiction of a known sample grid box;

FIG. 1B is a bottom view depiction of the known sample grid box of FIG. 1A;

FIG. 1C is a perspective depiction of a lid for the known grid box of FIGS. 1A and 1B;

FIG. 2A is a bottom view depiction of a sample grid box in accordance with the present teachings;

FIG. 2B is a is a perspective depiction of a lid, in accordance with the present teachings, for the grid box of FIG. 2A;

FIG. 2C is a top-view photograph of an embodiment of a grid box in accordance with the present teachings;

FIG. 2D is a photograph of the grid box of FIG. 2C mated with the lid of FIG. 2B;

FIG. 3A is a schematic cross-sectional depiction of a grid box compartment in accordance with the present teachings, showing the securing of the position of a known circular sample carrier;

FIG. 3B is a schematic cross-sectional depiction of a grid box compartment in accordance with the present teachings, showing the securing of the position of a non-circular sample carrier against rotational movement;

FIG. 3C is a schematic cross-sectional depiction of the grid box compartment of FIGS. 3A and 3B;

FIG. 4A is a depiction of a top view of a sample carrier apparatus in accordance with the present teachings as may be secured within a grid box compartment as depicted in FIG. 3C;

FIG. 4B is a depiction of a bottom view of the sample carrier apparatus depicted in FIG. 4A;

FIG. 5A is a depiction of a top view of another sample carrier apparatus in accordance with the present teachings as may be secured within a grid box compartment as depicted in FIG. 3C;

FIG. 5B is a is a depiction of a bottom view of the sample carrier apparatus of FIG. 5A;

FIG. 6A is a schematic depiction of a known sample grid gripper apparatus and its method of engagement with a sample grid;

FIG. 6B is a schematic depiction of a sample grid gripper apparatus in accordance with the present teachings and its method of engagement with a sample grid;

FIG. 7A is a depiction of a second sample grid box in accordance with the present teachings;

FIG. 7B is a depiction of a side view of spring arms and their associated spring-arm extensions of a sample grid stabilization apparatus in accordance with the present teachings; and

FIG. 7C is a perspective depiction of a sample grid stabilization apparatus in accordance with the present teachings.

### DETAILED DESCRIPTION

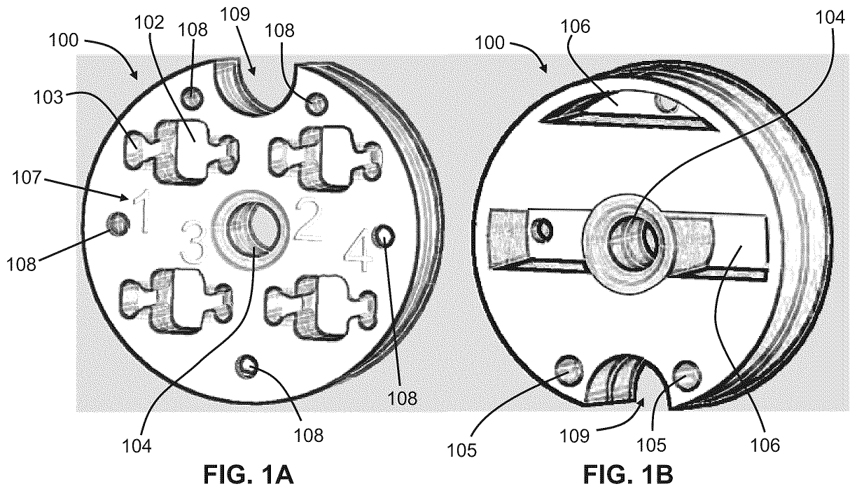

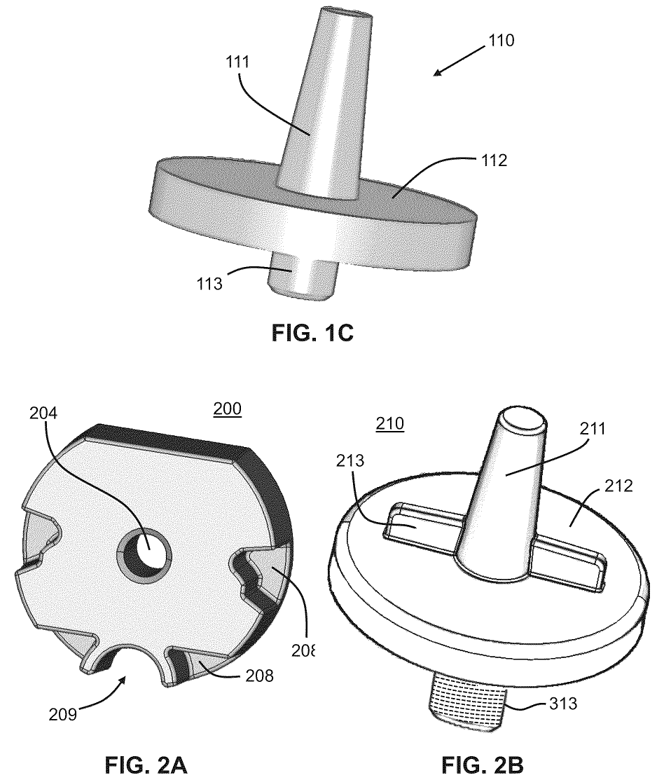

The following description is presented to enable any person skilled in the art to make and use the invention and is provided in the context of a particular application and its requirements. Various modifications to the described embodiments will be readily apparent to those skilled in the art and the generic principles herein may be applied to other embodiments. Thus, the present invention is not intended to be limited to the embodiments and examples shown but is to be accorded the widest possible scope in accordance with the features and principles shown and described. To fully appreciate the features of the present invention in greater detail, please refer to FIGS. 1A-1C, 2A-2D, 3A-3C, 4A-4B, 5A-5B, 6A-6B, and 7A-7C in conjunction with the following description.

In the description of the invention herein, it is understood that a word appearing in the singular encompasses its plural counterpart, and that a word appearing in the plural encompasses its singular counterpart, unless implicitly or explicitly understood or stated otherwise. Furthermore, it is understood that, for any given component or embodiment described herein, any of the possible candidates or alternatives listed for that component may generally be used individually or in combination with one another, unless implicitly or explicitly understood or stated otherwise. Moreover, it is to be appreciated that the figures, as shown herein, are not necessarily drawn to scale, wherein some of the elements may be drawn merely for clarity of the invention. Also, reference numerals may be repeated among the various figures to show corresponding or analogous elements. Additionally, it will be understood that any list of candidates or alternatives is merely illustrative, not limiting, unless implicitly or explicitly understood or stated otherwise.

Unless otherwise defined, all other technical and scientific terms used herein have the meaning commonly understood by one of ordinary skill in the art to which this invention belongs. In case of conflict, the present specification, including definitions, will control. It will be appreciated that there is an implied “about” prior to any quantitative terms mentioned in the present description, such that slight and insubstantial deviations are within the scope of the present teachings. In addition, the use of “comprise”, “comprises”, “comprising”, “contain”, “contains”, “containing”, “include”, “includes”, and “including” are not intended to be limiting. As used herein, “a” or “an” also may refer to “at least one” or “one or more.” Also, the use of “or” is inclusive, such that the phrase “A or B” is true when “A” is true, “B” is true, or both “A” and “B” are true.

FIG. 1A is a top view depiction of a known sample grid box. The grid box 100 that is shown in FIG. 1A comprises a plurality (in this example, four) of recessed grid compartments 102, each of which is for storage of a single respective sample-bearing sample carrier (sample carrier not shown in FIG. 1A). Each compartment has a respective compartment number (in this instance a number between 1 and 4) that is imprinted on the top surface of the grid box adjacent to the respective compartment. The grid box also comprises a plurality of small “satellite” recesses 103, pairs of which are contiguous with each recessed grid compartment 102. These satellite recesses are for the purpose of inserting a gripper device (e.g., tweezers) a distance below the top surface of the known grid box 100 during loading and unloading of sample grids from the compartments 102. Also shown is a lid-mounting hole 104 for insertion of a boss, threaded or unthreaded, of a lid apparatus for purposes of fastening the lid to the grid box. Still further, an alignment notch 109 is provided to ensure proper orientation of the grid box when it is mated with certain tooling and/or analytical apparatuses during analytical workflows. FIG. 1B is a depiction of the bottom of the grid box 100. The bottom face of the grid box 100 comprises gas intake holes 105 and gas intake cavities 106. The top face of the grid box comprises a plurality of circular gas outlet vents 108 that are fluidically coupled to the intake holes 105 and intake cavities 106. Together, the intake holes, intake cavities and outlet vents provide an exhaust system for gas generated by evaporation of cryogenic liquid underneath the grid box. However, it has been found that those cavities, holes and vents cause bubbling of gas at the grid box top face and can introduce contamination into the sample compartments.

FIG. 1C is a perspective depiction of a known lid 110 for the known grid box 100 of FIGS. 1A-1B. The lid 110 comprises a cover plate 112 for sealing engagement with the top surface of the grid box 100 so as to shield the grids contained therein from contamination. The lid also comprises, on its bottom side, a boss 113 that protrudes from the bottom side of the lid. As described above, the boss 113 is for fastening the lid to the grid box 100 by means of press fit engagement or threaded engagement with the hole 104 in the top surface of the grid box. An upper stem 111 protrudes from the top side of the lid plate and is shaped to engage with a lifting tool (not shown).

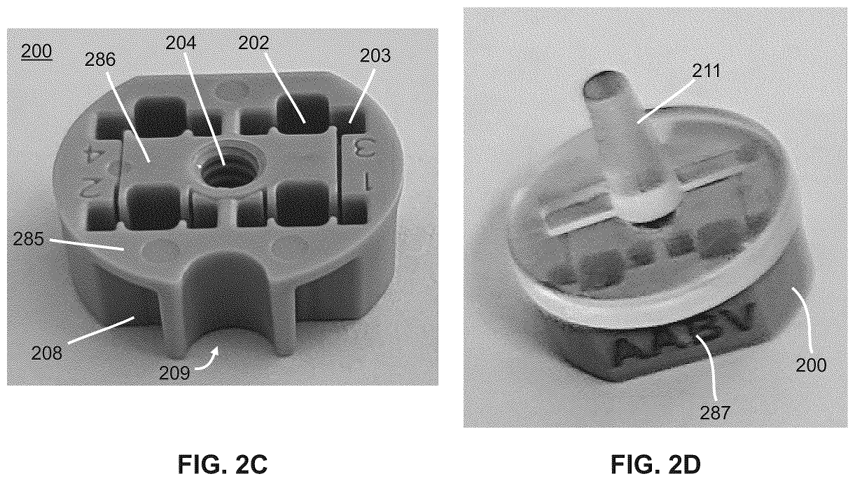

FIG. 2A is a bottom view depiction of a sample grid box 200 in accordance with the present teachings. The lid-mounting hole 204 of grid box 200 is analogous to the lid mounting hole 104 of the known grid box 100. Also, the alignment notch 209 is analogous to alignment notch 109 of the previously described grid box. In contrast to the known grid box 100 that is depicted in FIGS. 1A-1B, the grid box 200 does not have gas conduits that pass upwards through the interior of the device. Instead, the underside of the grid box 200 comprises gas dispersion pockets 208 through which gas resulting from evaporation of liquid below the device may escape. Such gas is directed, through the pockets 208 underneath the device to the outermost perimeter of the device. This configuration eliminates the need to direct vent gas upwards through the grid box. Further, the inventors have found that the gas dispersion pockets prevent any air or nitrogen gas from becoming trapped below the grid box when placing the box in liquid nitrogen. Thus, the provision of the gas dispersion pockets 208 reduces the risks of sample contamination or grid box floating.

FIG. 2B is a is a perspective depiction of a lid 210, in accordance with the present teachings, for the grid box 200 of FIG. 2A. The cover plate 212 and the stem 211 are analogous to plate 112 and stem 111 of the known grid box 100. The underside of the lid 210 comprises a threaded boss for 313 for screw-type engagement with and disengagement from the grid box 200. In contrast to the lid 110 that is shown in FIG. 1C, the lid 210 further comprises a pair of vertical fins 213 extending from the cover plate 212 on either side of the stem 211. The fins engage with mating grooves in a rotatable tool (not shown) so that additional torque may applied with attaching and detaching the lid from its associated grid box, via the threaded boss 313 and the mating threaded hole 204. Preferably the lid 210 is formed of a transparent material to allow visual inspection of the sample grids and their respective sample carriers within the grid box. Preferably, the material of which the lid is formed capable of withstanding, without cracking or significant deformation, multiple cycles of cooling to cryogenic temperatures and subsequent re-warming to room temperature.

FIG. 2C is a top-view photograph of the grid box 200. The grid box comprises recessed grid compartments 202, satellite recesses 203 and lid-mounting hole 204, which are analogous to compartments 102, recesses 103 and lid-mounting hole 104 of the grid box 100. The front view of grid box 200 also shows the alignment notch 209 and the outlets of the gas dispersion pockets 208 on the underside of the grid box.

FIG. 2D is a photograph of the lid 211 mounted onto the grid box 200. FIG. 2D also shows that the grid box 200 comprises an identification code 287 that is laser engraved onto one side of the grid box. The identification code consists of unique combination number of four letters and/or numbers and is clearly readable by eye, for easy recognition, even when the grid box is submerged in liquid nitrogen. It is estimated that the laser engraving can hold contrast even after thousands of cryogenic cycles.

Although the drawings and photographs herein are not executed in color, the inventors envision that the various grid boxes will comprise various different colors that may be recognized through the transparent lid. It is anticipated that users will employ the grid box colors to organize samples in any fashion they desire. Since the colors must be recognizable through both the lid as well as through a reservoir of liquid nitrogen, the various grid box instances should be formed in bright colors. Visual tests have demonstrated that, during normal use, a bright light green color appears to be better than gray, red, purple, light blue, dark blue, white, or transparent boxes.

Because only a limited number of readily distinguishable or highly visible colors may be available for use, some instances of the grid box may be formed in more than one color. Whereas single-color grid boxes may be formed as a single piece, multi-colored grid boxes may be formed in multiple pieces that are fastened together, with each piece formed in a different respective color. For example, FIG. 2C depicts a single instance of grid box 200 that is formed in two pieces of molded plastic. An inner section 286, molded in a first color, is fastened to an outer plastic piece 285 that is molded in a second color.

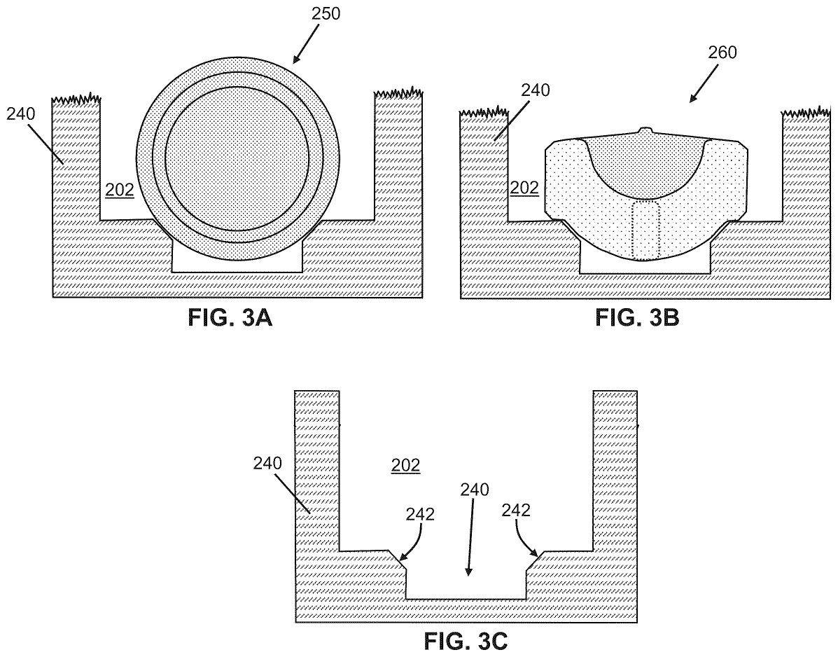

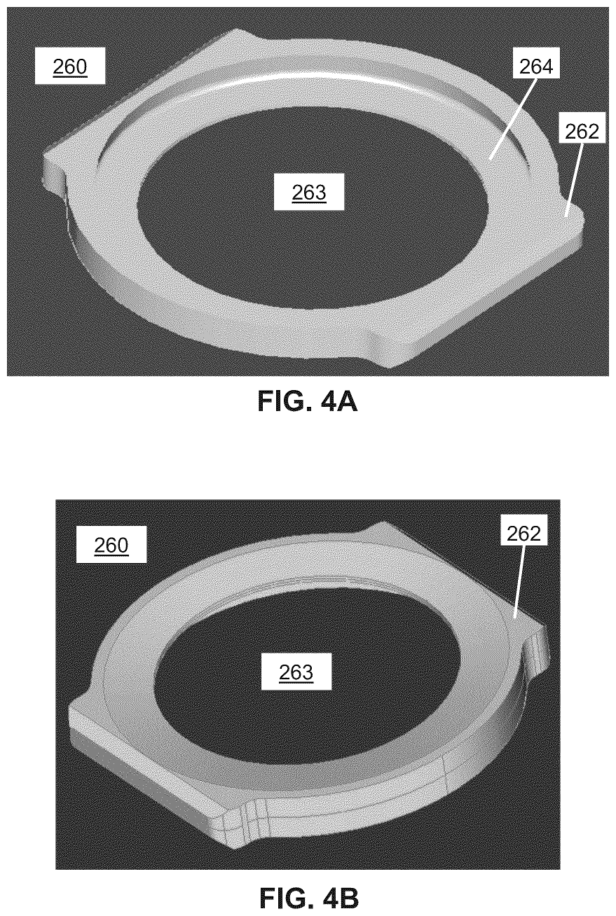

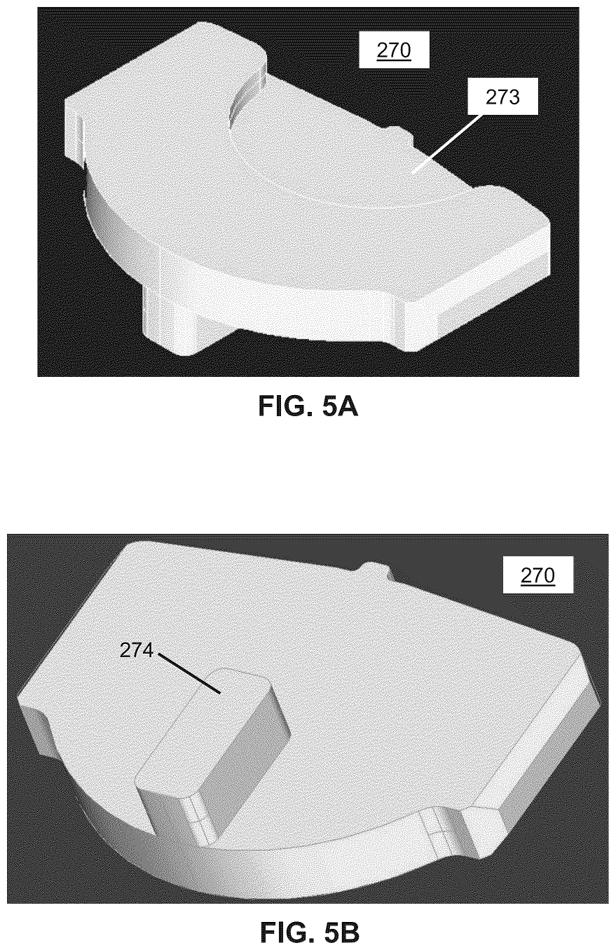

FIGS. 3A-3C are cross-sections through a sample compartment 202 of some embodiments of the grid box 200. The shape of the bounding walls 240 of the compartment 202 (as shown in FIG. 3C) are designed to accommodate sample carriers of different shapes. For example, FIG. 3A illustrates a conventional circular sample carrier 250 disposed within the grid box. Likewise, FIG. 3B illustrates a sample carrier comprising a different shape disposed within the same grid box. Top and bottom perspective views of this sample carrier are depicted in FIGS. 5A and 5B. FIGS. 4A and 4B are top and bottom perspective views of a differently shaped sample carrier 260 that may be accommodated within the same grid box 200. The sample carrier 260 may be used to carry a standard circular mesh grid structure on which sample particles that are embedded in vitreous ice are disposed. Thus, the sample carrier 260 and the grid box in which it is disposed may be employed for cryogenic electron microscopy. In operation, the mesh grid (not shown) may reside on a recessed circular platform 264 having a central opening 263 that, in operation, may be spanned by a mesh grid. Advantageously, the differently shaped sample carriers 250, 260 and 270 may be simultaneously mounted within a single grid box of the type shown.

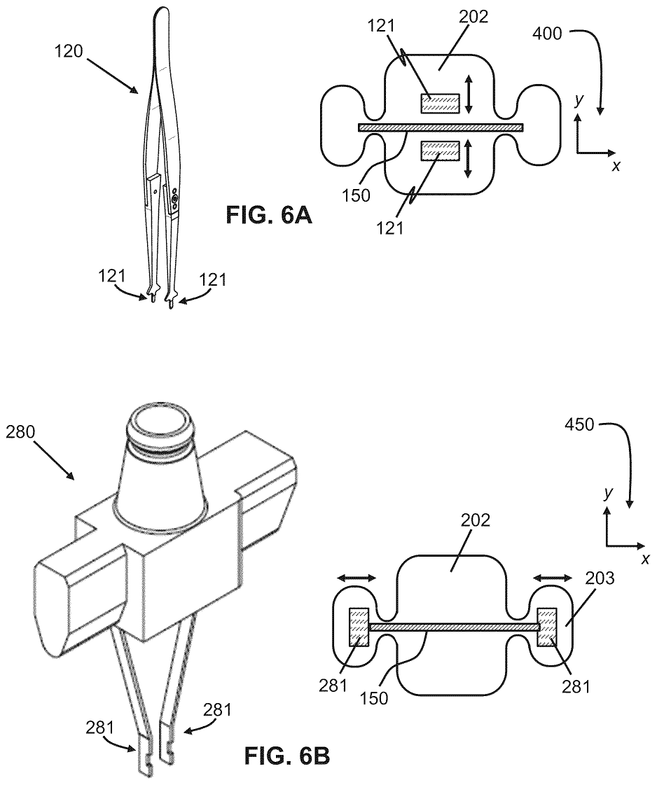

FIG. 6A is a schematic depiction of a known sample grid gripper apparatus 120 and its known method of engagement with a sample carrier 150. According to the method, a manually operated gripper apparatus 120, which is essentially a special set of tweezers having specially shaped tines 121, is used to both insert a sample carrier 150 into a compartment 202 of a grid box and remove the sample carrier from the grid compartment. Frequently, a user may need to insert and remove a sample carrier multiple times during a typical analytical workflow. According to the known method, the sample carrier 150 together with its grid is inserted and removed from the grid compartment while the tines 121 grasp the sample carrier at opposite sides of a short dimension of the carrier. Note that, in this discussion, the terms “short” and “long” are utilized only in a relative sense. As an example, referring to the set of axes 400 in FIG. 6A, the short dimension of the sample carrier is parallel to the y-axis and the long dimension is parallel to the x-axis. Cross sections of the tines 121, as shown on the right-hand side of FIG. 6A indicate that the tines are disposed at opposite sides of the short dimension of the sample carrier. Because the tines 121 are not widely separated from one another during engagement with and subsequent transport of the sample carrier with its grid, there is a risk that the sample tilt or otherwise rotate to into an improper orientation during the engagement.

FIG. 6B is a schematic depiction of a sample grid gripper apparatus 280 in accordance with the present teachings and its method of engagement, in accordance with the present teachings, with a sample carrier within a grid box. The gripper apparatus 280 is designed to be operated by a robotic apparatus instead of manually, as was described in reference to FIG. 6A. Referring to the axes 450 in FIG. 6B, it may be observed that the gripper apparatus is oriented relative to the grid such that the tines 281 of the gripper apparatus 280 engage the sample carrier 150 at opposite ends of its long dimension, which is parallel to the indicated x-axis. Because, upon engagement with the sample carrier 150, the tines 281 are more widely separated from one another than are the tines 121, the proper angular orientation of the sample carrier may be more readily preserved during lifting, transport, and insertion of the sample carrier 150. The preservation of the proper orientation of the sample grid during handling is useful for ensuring that the grid will arrive at a destination apparatus (e.g., an entrance port of an electron microscope) having an orientation that is accepted by that apparatus.

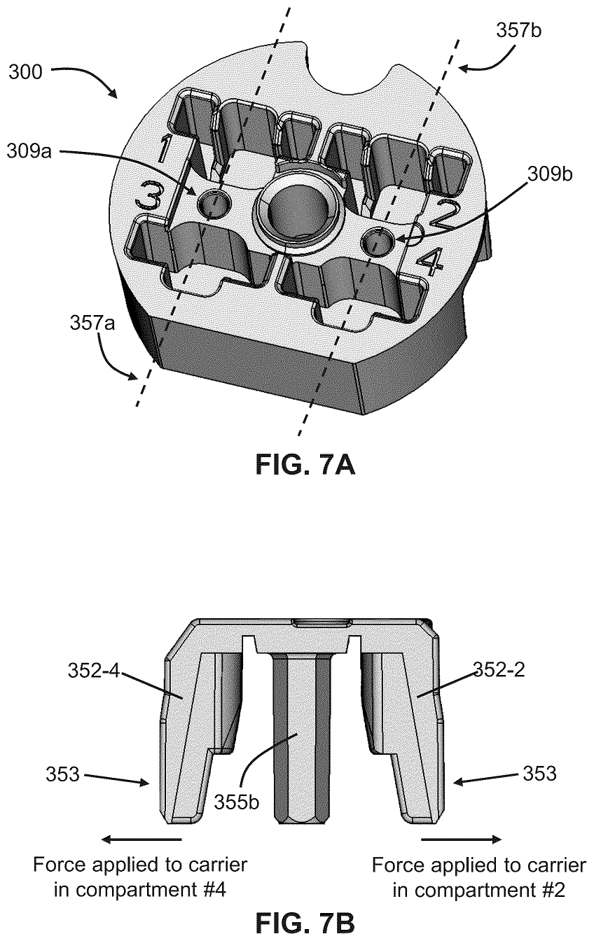

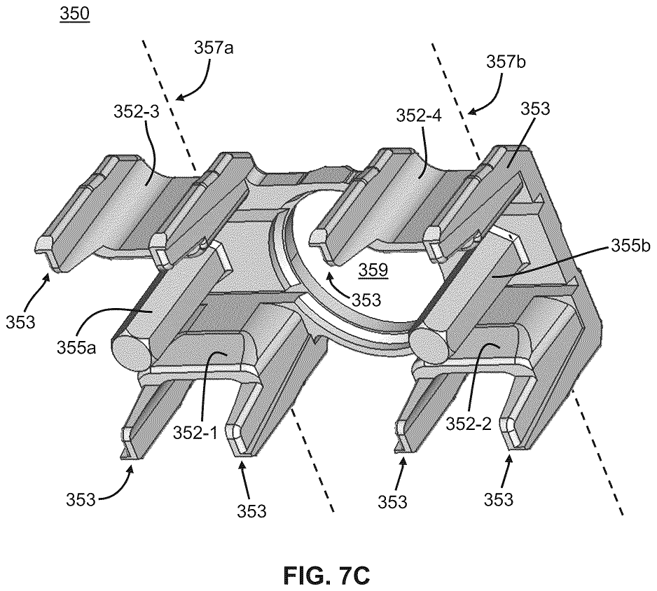

FIG. 7A is a depiction of a second sample grid box 300 in accordance with the present teachings. The grid box 300 of FIG. 7A is essentially identical to the grid box 200 (e.g., FIG. 2C) except for the provision of two additional holes 309a, 309b. These two additional holes are provided for, in operation, receiving each of two pins 355a, 355b of a spring mechanism 350, the main body of which is depicted in FIG. 7C. FIG. 7B depicts a portion of the spring mechanism 350, which is here referred to as a sample grid stabilization apparatus. When the sample grid stabilization apparatus 350 and the grid box 300 are assembled together, the pin 355b that is depicted in FIG. 7B is press fit into hole 309b and the pin 355a (FIG. 7C) is press fit into hole 309a. The sample grid stabilization apparatus has an opening 359 that is aligned such that, in operation, at least a portion of the boss 313 of the grid box lid 210 (FIG. 2B) protrudes through the stabilization apparatus into the lid mounding hole 204.

The dashed line 357b in FIG. 7A represents the alignment axis (not a solid physical component of the apparatus) of two spring arms, 352-2 and 352-4 of a total of four such spring arms. The other two spring arms are labeled 352-1 and 352-3 and aligned along axis 357a (FIG. 7C). In the assembled form of the grid box and stabilization apparatus, the spring arm 352-4 provides an outward-directed and/or downward-directed spring force, as depicted by the leftmost arrow in FIG. 7B, to the sample carrier in the grid box compartment labeled “4” (on the top of the grid box). Another spring arm 352-2 provides an outward-directed and/or downward-directed spring force, as depicted by the rightmost arrow, to the sample carrier in the compartment labeled “2”. Similarly, another spring arm 352-1 provides outward and/or downward directed securing forces to the sample carrier in compartment “1” and spring arm 352-3 provides outward-directed and/or downward directed securing spring forces to the sample carrier in compartment “3”.

As best depicted in FIG. 7C, each spring arm comprises two spring-arm extensions 353. Each spring-arm extension of each pair of spring-arm extensions engages with a single side of a sample carrier, with the pair of extensions engaging opposing sides of the same sample carrier. For example, the two spring-arm extensions 353 depicted on the lower right-hand side of FIG. 7C, both of which are contiguous with spring arm 352-2, engage with opposing sides of the sample carrier in the sample compartment that is labeled “2” (see FIG. 7B). Accordingly, each sample carrier is secured in place against lateral and rotational movements by two spring arm extensions. With the sample grid stabilization apparatus 350 assembled together with a grid box 300 that comprises four sample compartments that contain respective sample carriers that have samples thereon, each spring arm provides a force that tends to urge the associated sample carrier into friction contact engagement with a wall or a floor of the associated sample compartment, thereby securing the position of the carrier.

1. A grid box assembly for holding a plurality of sample-bearing grids for cryo-electron microscopy comprising:
a grid box comprising a plurality of compartments, each compartment adapted to hold a respective sample-bearing sample carrier; and
a sample grid stabilization apparatus comprising a plurality of spring arms, wherein each spring arm provides a spring force to a respective sample carrier that secures the position of the sample carrier within its respective compartment.

2. A grid box assembly as recited in claim 1, further comprising:
a lid adapted to cover a top surface of the grid box.

3. A grid box assembly as recited in claim 2, wherein the lid is transparent.

4. A grid box assembly as recited in claim 2 wherein the lid comprises:
a cover plate;
a boss extending from a lower surface of the cover plate for fastening the lid to the grid box; and
a stem and a pair of fins extending from an upper surface of the cover plate for engagement with a tool that rotates the lid for attachment to and detachment from the grid box.

5. A grid box assembly as recited in claim 1, wherein the sample grid stabilization apparatus is fabricated from polycarbonate.

6. A grid box assembly as recited in claim 1, further comprising:
a perimeter surface of the grid box that is engraved with a unique identifying coding.

7. A grid box assembly as recited in claim 1, wherein the grid box is color coded with two or more identifying colors.

8. A grid box assembly for holding a plurality of sample-bearing grids for electron microscopy comprising:
a grid box comprising a plurality of compartments, each compartment adapted to hold a respective sample-bearing sample carrier; and
a lid adapted to cover a top surface of the grid box,
wherein a bottom surface of the grid box comprises a plurality of gas dispersion pockets that extend to the perimeter of the grid box and through which gas resulting from evaporation of liquid below the device may escape.

9. A grid box assembly as recited in claim 8, wherein the lid is transparent.

10. A grid box assembly as recited in claim 8, wherein the lid comprises:
a cover plate;
a boss extending from a lower surface of the cover plate for fastening the lid to the grid box; and
a stem and a pair of fins extending from an upper surface of the cover plate for engagement with a tool that rotates the lid for attachment to and detachment from the grid box.

11. A grid box assembly as recited in claim 10, further comprising:
a perimeter surface of the grid box that is engraved with a unique identifying coding.

12. A grid box assembly as recited in claim 10, wherein the grid box is color coded with two or more identifying colors.

13.-15. (canceled)

16. A kit for use in storage of cryo-electron microscopy samples comprising:
one or more grid boxes, each grid box comprising a plurality of sample compartments for storing sample-bearing sample carriers;
a plurality of lids, each lid adapted to engage with a top surface of any one of the grid boxes; and
one or more sample grid stabilization apparatuses, each of which comprises a plurality of spring arms, wherein each spring arm is configured to provide, when coupled to a grid box, a spring force to a respective sample carrier within the grid box that secures the position of the sample carrier within its respective compartment.

17. A kit as recited in claim 16, wherein the sample grid stabilization apparatus is fabricated from polycarbonate.

18. A kit as recited in claim 16, wherein a perimeter surface of each grid box is engraved with a respective unique identifying coding.

19. A kit as recited in claim 16, wherein at least one grid box the grid box is color coded with two or more identifying colors.

20. A kit as recited in claim 16, wherein each grid box comprises a bottom surface that comprises a plurality of gas dispersion pockets that extend to the perimeter of the said each grid box.
